(19) United States
(12) Patent Application Publication
(10) Pub. No.: US 2015/0173249 A1
(43) Pub. Date: Jun. 18, 2015

(54) DATA STORAGE DEVICE ENCLOSURE AND COOLING SYSTEM

(71) Applicant: KABUSHIKI KAISHA TOSHIBA, Tokyo (JP)

(72) Inventor: Michael C. MCGRATH, Pleasanton, CA (US)

(73) Assignee: KABUSHIKI KAISHA TOSHIBA, Tokyo (JP)

(21) Appl. No.: 14/109,453

(22) Filed: Dec. 17, 2013

(51) Int. Cl. H05K 7/20; H05K 7/14

(52) U.S. Cl. CPC H05K 7/20718; H05K 7/1488

(57) ABSTRACT

A housing for a data storage device is configured to enhance and direct cooling airflow across heat-generating components of the data storage device with an enclosure that has an air supply opening formed in a floor portion of the enclosure and an air exhaust opening formed in a ceiling portion of the enclosure. In addition, a mounting plate for a first data storage device and a mounting plate for a second data storage device may form a vertically-oriented cavity in which a printed circuit board of the data storage device is to be installed.

### BACKGROUND

As desktop electronic devices are progressively miniaturized, such as server processors, data storage devices, and other computer appliances, heat removal from such devices has become increasingly problematic. Simply stated, power consumption of miniaturized electronic devices, and the heat generation directly related thereto, has not scaled down in proportion to the size of such devices. In fact, in the case of many processors and stacked chips, power consumption has increased as chip area has decreased. Consequently, more heat must be dissipated from smaller volumes to prevent undesirable overheating of many electronic devices.

This is particularly true for electronic devices that are typically utilized in high-density configurations, such as computer appliances. For example, in cloud computing, server processors and network-attached storage devices may be used in stacked or rack-mounted arrays. Frequently, the devices in such arrays are positioned in contact or near-contact with adjacent devices. This can result in blocked inlets and outlets for air to cool these devices, reducing heat dissipation and increasing the risk of overheating. In light of the above, there is a need in the art for more robust cooling capability for electronic devices.

### SUMMARY

Embodiments provide systems for robust heat dissipation in an electronic device. Specifically, a housing for a data storage device is configured to enhance and direct cooling airflow across heat-generating components of the data storage device. In some embodiments, the housing is also configured to facilitate side-by-side positioning of multiple instances of the data storage device and to prevent air inlet and air outlet openings of each of the multiple data storage devices from being blocked.

According to one embodiment of the present invention, a housing for a data storage device includes a single support pedestal, a first mounting plate for a first data storage device, coupled to the support pedestal, a second mounting plate for a second data storage device, coupled to the support pedestal, and an enclosure. The enclosure is for the first data storage device and the second data storage device, and has an air supply opening formed in a floor portion of the enclosure and an air exhaust opening formed in a ceiling portion of the enclosure.

According to another embodiment of the present invention, a data storage apparatus includes a single support pedestal, a first mounting plate, a second mounting plate, a first data storage device, a second data storage device, and an enclosure for the first and second data storage devices. The first mounting plate is coupled to the support pedestal and to the first data storage device and the second mounting plate is coupled to the support pedestal and to the second data storage device. The enclosure has an air supply opening formed in a floor portion of the enclosure and an air exhaust opening formed in a ceiling portion of the enclosure, where a center of gravity of the data storage apparatus is aligned substantially vertically with a load-bearing axis of the support pedestal.

### BRIEF DESCRIPTION OF THE DRAWINGS

So that the manner in which the above recited features of the embodiments can be understood in detail, a more particular description of the embodiments, briefly summarized above, may be had by reference to the appended drawings. It is to be noted, however, that the appended drawings illustrate only typical embodiments and are therefore not to be considered limiting of its scope, for there may be other equally effective embodiments.

FIG. 1 is a cross-sectioned perspective view of an electronic device configured according to an embodiment.

FIG. 2 is a plan view of the electronic device in FIG. 1, arranged according to an embodiment.

FIG. 3 is an elevation view of one end of the electronic device in FIG. 1, arranged according to an embodiment.

FIG. 4 is an elevation view of one end of the electronic device in FIG. 1, in which the enclosure has been removed.

FIG. 5 is a cross-sectioned perspective view of the electronic device in FIG. 1 in which the enclosure has been removed.

FIG. 6 is an elevation view of a plurality of electronic devices arranged in a side-by-side array according to an embodiment.

For clarity, identical reference numbers have been used, where applicable, to designate identical elements that are common between figures. It is contemplated that features of one embodiment may be incorporated in other embodiments without further recitation.

### DETAILED DESCRIPTION

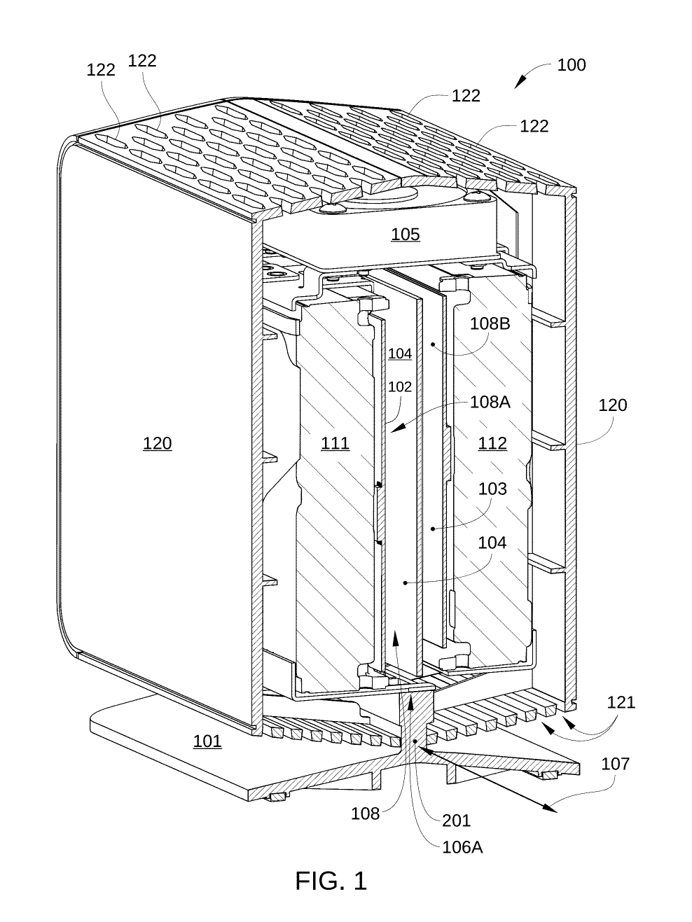

FIG. 1 is a cross-sectioned perspective view of an electronic device 100 configured according to an embodiment. Electronic device 100 is a heat-generating electronic device, such as a network-attached storage (NAS) device with two or more storage devices, or any other data storage apparatus or computer appliance. For example, electronic device 100 may include multiple server processors, routers, anti-spam appliances, or any other network appliance or virtual machine appliance. When configured as a NAS, electronic device 100 may be configured for mass data storage use by an individual consumer or as a part of a distributed computing system.

As shown, electronic device 100 includes a support pedestal 101, a first mounting plate 102, a second mounting plate 103, a printed circuit board 104, a fan 105, a first heat-generating component 111, a second heat-generating component 112, and an enclosure 120. First mounting plate 102 and second mounting plate 103 are generally coupled to support pedestal 101, and printed circuit board 104 may be coupled to either first mounting plate 102, second mounting plate 103, or support pedestal 101. First heat-generating component 111 is coupled to first mounting plate 102, second heat-generating component 112 is coupled to second mounting plate 103, and fan 105 may be mounted on first mounting plate 102, second mounting plate 103, or a combination thereof. Enclosure 120 is configured so that the above-described components of electronic device 100 are disposed within enclosure 120.

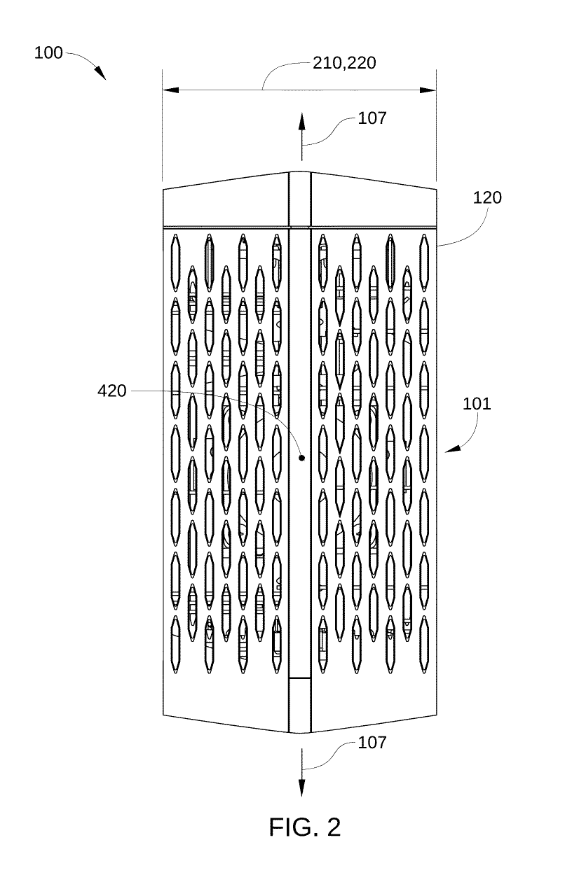

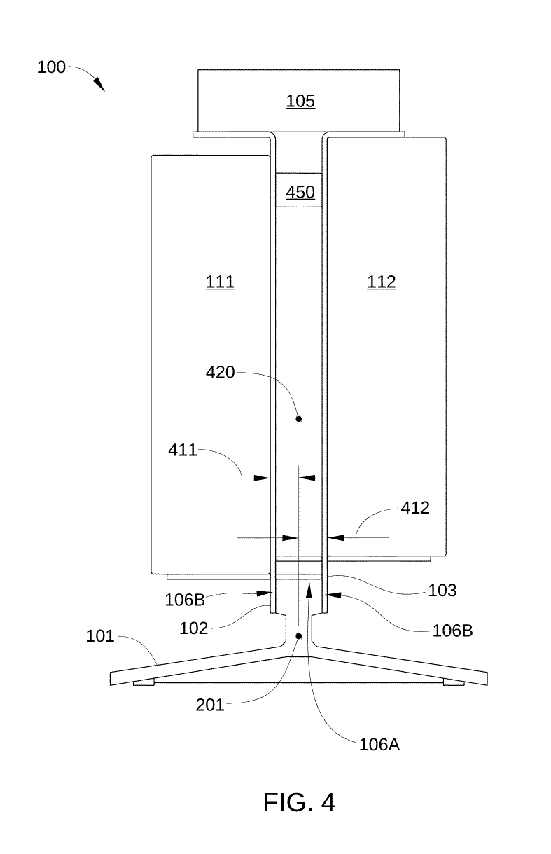

Support pedestal 101 is configured as a structural base for electronic device 100, to which first heat-generating component 111, second heat-generating component 112, and enclosure 120 are coupled. In some embodiments, printed circuit board 104 is also coupled to support pedestal 101, and in other embodiments, printed circuit board 104 is instead coupled to first mounting plate 102 and/or second mounting plate 103, as described below. In some embodiments, support pedestal 101 is configured with a top surface 106A and/or side surfaces 106B (for clarity shown in FIG. 4) that extend along a direction that is substantially parallel to a load-bearing axis 107 of support pedestal 101. Load-bearing axis 107 extends along the length of support pedestal 101, is parallel to an axis of symmetry of support pedestal 101, and passes through the center of gravity of support pedestal 101. Thus, in such embodiments, load-bearing axis 107 extends along the length of support pedestal 101, as indicated in FIGS. 1 and 2

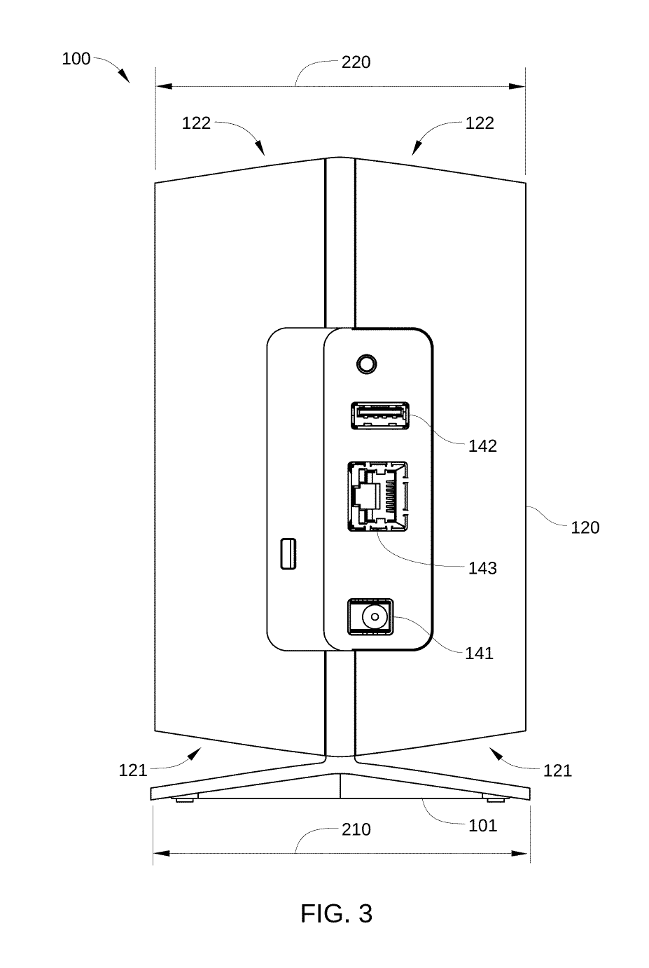

FIG. 2 is a plan view of electronic device 100 arranged according to an embodiment. As shown, load-bearing axis 107 extends along the length of support pedestal 101 and electronic device 100, is parallel to an axis of symmetry of support pedestal 101, and passes through a center of gravity 201 (shown in FIG. 1) of support pedestal 101. In addition, in some embodiments, support pedestal 101 is configured with a footprint that does not extend beyond a footprint of enclosure 120, where the “footprint” of an object may be considered the outline of the object when projected onto a horizontal surface below the object. For example, in some embodiments, support pedestal 101 has a footprint that does not extend significantly beyond the footprint of enclosure 120 when support pedestal 101 has a length that is no longer than that of enclosure 120, has a width 210 that is no greater than a width 220 of enclosure 120, and is substantially vertically aligned with enclosure 120. Width 210 of support pedestal 101 and width 220 of enclosure 120 are also illustrated more clearly in FIG. 3.

FIG. 3 is an elevation view of one end of electronic device 100 arranged according to an embodiment. As shown, width 210 of support pedestal 101 is not significantly greater than width 220 of enclosure 120, and the footprint of support pedestal 101 does not extend significantly beyond the footprint of enclosure 120. Consequently, electronic devices 100 that are disposed adjacent to each other can be positioned with enclosures 120 in contact or in near-contact, thereby maximizing utilization of space without impacting heat removal from electronic devices 100. Heat removal from enclosure 120 is described in greater detail below.

Returning to FIG. 1, first mounting plate 102 and second mounting plate 103 are coupled to support pedestal 101, in some embodiments via one or more support surfaces. For example, first mounting plate 102 and second mounting plate 103 may be coupled to a top surface 106A of support pedestal 101 or mounted to one or more side surfaces 106B of support pedestal 101. When coupled to support pedestal 101 via top surface 106A and/or side surfaces 106B, first mounting plate 102 and second mounting plate 103 can be positioned substantially symmetrically on opposite sides of load-bearing axis 107. In addition, first mounting plate 102 and second mounting plate 103 may be coupled to each other to form a rigid support structure. One such embodiment is illustrated in FIG. 4.

FIG. 4 is an elevation view of one end of electronic device 100, arranged according to an embodiment. Enclosure 120 is omitted in FIG. 4 for clarity. As shown, first mounting plate 102 and second mounting plate 103 are each coupled to support pedestal 101 via top surface 106A and/or side surfaces 106B. Furthermore, first mounting plate 102 and second mounting plate 103 are positioned substantially symmetrically on opposite sides of load-bearing axis 107. It is noted that load-bearing axis 107 extends out of the page, passing through center of gravity 201, and therefore is not visible in FIG. 4. In the embodiment illustrated in FIG. 4, first mounting plate 102 and second mounting plate 103 are configured to respectively fix first heat-generating component 111 and second heat-generating component 112 so that a horizontal displacement 411 between first heat-generating component 111 and load-bearing axis 107 is substantially equal to a horizontal displacement 412 between second heat-generating component 112 and load-bearing axis 107. In this way, electronic device 100 is rendered more stable, since a center of gravity 420 of electronic device 100 is aligned substantially vertically above center of gravity 201 and load-bearing axis 107 and there is no tendency for electronic device 100 to tip or tilt to one side. In addition, in the embodiment illustrated in FIG. 4, first mounting plate 102 and second mounting plate 103 are also coupled to each other, for example via a bracket 450.

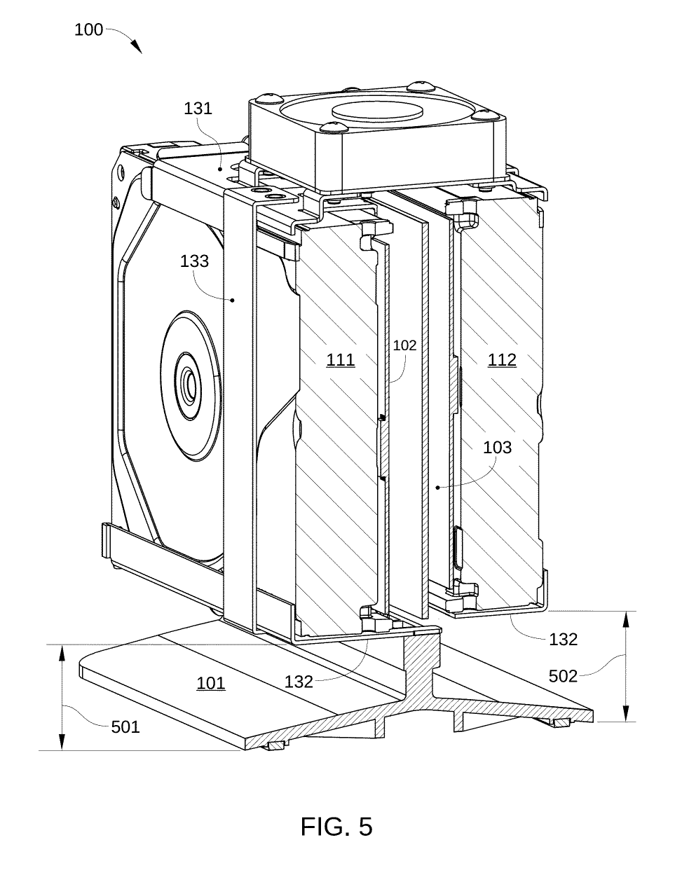

Returning to FIG. 1, first mounting plate 102 is configured to couple first heat-generating component 111 to support pedestal 101, and second mounting plate 103 is configured to couple second heat-generating component 112 to support pedestal 101. In some embodiments, first mounting plate 102 and/or second mounting plate 103 are also configured to mount printed circuit board 104 to support pedestal 101. In some embodiments, first mounting plate 102 and second mounting plate 103 are configured with additional structural elements, which are more clearly illustrated in FIG. 5. FIG. 5 is a cross-sectioned perspective view of electronic device 100, in which enclosure 120 has been omitted. As shown, first mounting plate 102 and second mounting plate 103 each include upper support bracket portions 131, lower support bracket portions 132, and/or side straps 133 to more securely fix heat-generating components 111 and 112 in place.

In some embodiments, first heat-generating device 111 and second heat-generating component 112 are vertically offset from each other. In such embodiments, interference is prevented between the connector pins used to electrically couple heat-generating component 111 to printed circuit board 104 and the connector pins used to electrically couple heat-generating component 112 to printed circuit board 104. In such embodiments, first mounting plate 102 is configured to fix first heat-generating component 111 at a first height 501 above a bottom surface of support pedestal 101 and the second mounting plate is configured to fix second heat-generating component 112 at a second height 502 above a bottom surface of support pedestal 101. Thus, because second height 502 is not equal to first height 501, first heat-generating component 111 is vertically offset from second heat-generating component 112.

In some embodiments, first mounting plate 102 and second mounting plate 103 form a vertically-oriented cavity 108 (shown in FIG. 1) in which printed circuit board 104 is installed. Vertically-oriented cavity 108 may be configured to guide air from a plurality of air supply openings 121 in enclosure 120 to a plurality of air exhaust openings 122 in enclosure 120. In such embodiments, vertically-oriented cavity 108 is defined by a first planar surface 108A of first mounting plate 102 and a second planar surface 1088 of second mounting plate 103. Thus, first mounting plate 102 may be configured to guide air from air supply openings 121 across a surface of first heat generating component 111 that faces vertically-oriented cavity 108 and second mounting plate 103 may be configured to guide air from air supply openings 121 across a surface of second heat-generating component 112 that faces vertically-oriented cavity 108. For example, first mounting plate 102 and second mounting plate 103 may have openings and deflector features as required to guide the air flow as required for improved cooling. In such embodiments, first mounting plate 102 may be substantially parallel to second mounting plate 103, as shown in FIG. 1. It is noted that the position of air supply openings 121 and air exhaust openings 122 provide efficient passive convection when fan 105 is turned off or in embodiments that do not include fan 105. Thus, heat generated in enclosure 120 generates vertical airflow through air supply openings 121 and air exhaust openings 122.

Printed circuit board 104 may be any technically feasible circuit board configured to facilitate the connection of power and/or input/output (I/O) signals to heat-generating components 111 and 112. As shown in FIG. 3, power and/or I/O connections on printed circuit board 104 may include a power connector 141, a universal serial bus (USB) connector 142, and an Ethernet connector 143 (or other network connector), among others.

Fan 105, shown in FIG. 1, may be any technically feasible air-moving device, and is configured to draw cooling air into air supply openings 121 and force air out of air exhaust openings 122. Fan 105 facilitates the removal of heat generated by first heat-generating component 111, second heat-generating component 112, and printed circuit board 104. Specifically, fan 105 draws air from air supply openings 121 through vertically-oriented cavity 108, and draws air over the outward facing surfaces of heat-generating components 111 and 112. In addition, fan 105 is positioned above the first mounting plate and the second mounting plate. Consequently, because heat-generating components 111 and 112 are typically much heavier and denser than fan 105, the center of gravity 420 (shown in FIG. 4) of electronic device 100 is significantly lower than when fan 105 is mounted below first heat-generating component 111 and second heat-generating component 112. With a lower center of gravity, electronic device 100 is more stable and less likely to be overturned.

First heat-generating component 111 and second heat-generating component 112 may be any electronic devices that generate sufficient heat during operation that overheating may occur if the generated heat is not dissipated or otherwise removed from electronic device 100. For example, first heat-generating component 111 and second heat-generating component 112 may be hard disk drives or solid-state drives, as in a NAS, server processors, routers, or other computer appliances. In the embodiment illustrated in FIGS. 1-5, first heat-generating component 111 and second heat-generating component 112 are each hard disk drives.

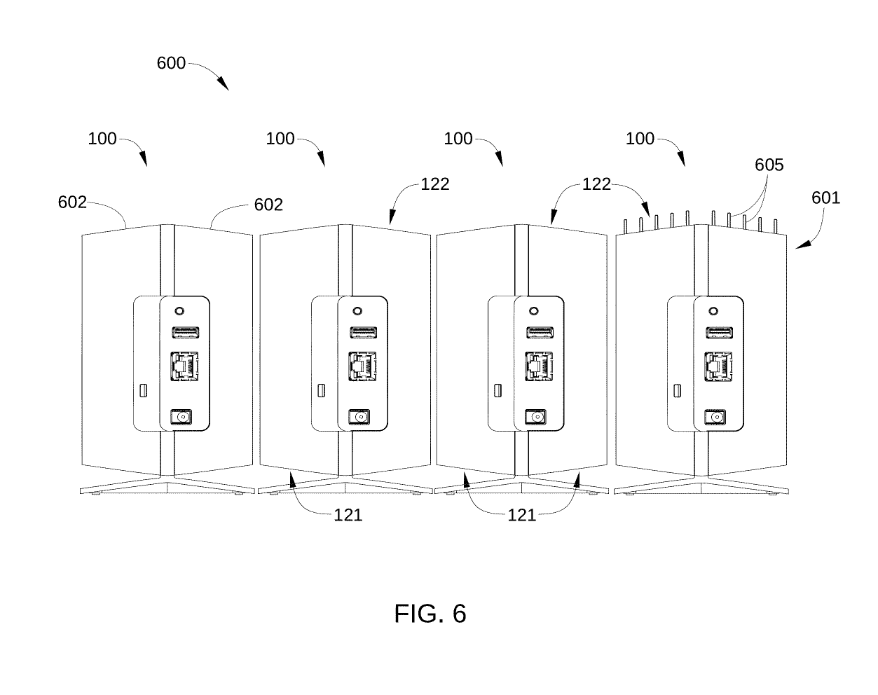

Enclosure 120 houses and protects first heat-generating component 111 and second heat-generating component 112, while facilitating the cooling thereof during operation. Thus, enclosure 120 includes air supply openings 121 formed in a floor portion and air exhaust openings 122 formed in a ceiling portion. It is noted that air supply openings 121 and air exhaust openings 122 are positioned so that vertically-oriented cavity 108 guides air from air supply openings 121 to air exhaust openings 122, enhancing heat dissipation from first heat-generating component 111 and second heat-generating component 112. Thus, there is no need for air supply or air exhaust openings on the vertically-oriented sides of enclosure 120, and electronic device 100 can be placed adjacent to other similar electronic devices in a high-density, side-by-side array without reducing air flow through enclosure 120. FIG. 6 illustrates one such array.

FIG. 6 is an elevation view of a plurality of electronic devices 100 arranged in a side-by-side array 600 according to an embodiment. As shown, each of electronic devices 100 can be proximate or even in contact with adjacent electronic devices 100 without blocking air supply openings 121 formed in a floor portion of each enclosure 120 and air exhaust openings 122 formed in a ceiling portion 601 of each enclosure 120. Furthermore, in some embodiments, ceiling portion 601 of enclosure 120 may be configured to prevent objects placed on top of electronic device 100 from substantially blocking air exhaust openings 122. For example, in some embodiments, ceiling portion 601 includes two top surfaces that are each angled at least about 8 degrees from horizontal, and/or a top surface that is concave, and/or a top surface that is convex. In this way, flat objects placed on top of ceiling portion 601 cannot completely block air exhaust openings 122. In addition, ceiling portion 601 can be configured so that it does not provide a stable platform for most objects, making it less likely that objects will be placed on top of electronic device 100 and reduce the airflow for cooling. In the embodiment illustrated in FIG. 6, electronic devices 100 include two top surfaces 602 that are each angled at least about 8 degrees from horizontal. In this embodiment, a flat object placed on electronic device 100 can only block about half of air exhaust openings 122 in a particular enclosure 120. In some embodiments, ceiling portion 601 may include one or more projections 605 extending away from top surface 602. Projections 605 may discourage placement of objects on top surface 602 and prevent objects placed on top surface 602 from substantially blocking air exhaust openings 122.

In sum, embodiments described herein provide systems and methods for robust heat dissipation in an electronic device. In one embodiment, a housing for a data storage device is configured to enhance and direct cooling airflow across heat-generating components of the data storage device with an enclosure that has an air supply opening formed in a floor portion of the enclosure and an air exhaust opening formed in a ceiling portion of the enclosure. A mounting plate for a first data storage device and a mounting plate for a second data storage device may form a vertically-oriented cavity in which a printed circuit board for the first and second data storage devices is to be installed. Because no air supply or exhaust openings are formed on side surfaces of the enclosure, multiple instances of such a data storage device can advantageously be arranged in contact with each other without adversely affecting heat removal therefrom.

While the foregoing is directed to specific embodiments, other and further embodiments may be devised without departing from the basic scope thereof, and the scope thereof is determined by the claims that follow.

I claim:

1. A housing for a data storage device comprising:
a single support pedestal;
a first mounting plate for a first data storage device, coupled to the support pedestal;
a second mounting plate for a second data storage device, coupled to the support pedestal; and
an enclosure for the first data storage device and the second data storage device having an air supply opening formed in a floor portion of the enclosure and an air exhaust opening formed in a ceiling portion of the enclosure.

2. The housing of claim 1, wherein the first mounting plate and the second mounting plate form a vertically-oriented cavity in which a printed circuit board of the data storage device is to be installed.

3. The housing of claim 2, wherein the vertically-oriented cavity is configured to guide air from the air supply opening to the air exhaust opening.

4. The housing of claim 2, wherein the vertically-oriented cavity is defined by a first planar surface of the first mounting plate and a second planar surface of the second mounting plate.

5. The housing of claim 1, wherein the first mounting plate is configured to guide air from the air supply opening across the first data storage device and the second mounting plate is configured to guide air from the air supply opening across the second data storage device.

6. The housing of claim 1, wherein the first mounting plate is substantially parallel to the second mounting plate.

7. The housing of claim 1, wherein the first mounting plate is configured to fix the first storage device at a first height above the support pedestal and the second mounting plate is configured to fix the second storage device at a second height above the support pedestal, the second height being vertically offset from the first height.

8. The housing of claim 1, further comprising a cooling fan mounted inside the housing and above the first mounting plate and the second mounting plate.

9. The housing of claim 1, wherein the ceiling portion of the housing includes at least one of a top surface that is angled at least about 8 degrees from horizontal, a top surface that is concave, or a top surface that is convex.

10. The housing of claim 1, wherein the ceiling portion of the housing includes a top surface having one or more projections extending away from the top surface.

11. The housing of claim 1, wherein a footprint of the support pedestal does not extend significantly beyond a footprint of the housing.

12. The housing of claim 1, wherein a center of gravity of the housing is aligned substantially vertically with a load-bearing axis of the support pedestal.

13. The housing of claim 12, wherein the load-bearing axis extends along a direction that is substantially parallel to a longitudinal axis of the support pedestal.

14. A data storage apparatus comprising:
a single support pedestal;
a first mounting plate coupled to the support pedestal and to a first data storage device;
a second mounting plate coupled to the support pedestal and to a second data storage device;
an enclosure for the first and second data storage devices having an air supply opening formed in a floor portion of the enclosure and an air exhaust opening formed in a ceiling portion of the enclosure,
wherein a center of gravity of the data storage apparatus is aligned substantially vertically with a load-bearing axis of the support pedestal.

15. The data storage apparatus of claim 14, wherein the load-bearing axis extends along a direction that is substantially parallel to a longitudinal axis of the support pedestal.

16. The data storage apparatus of claim 15, wherein the first data storage device is positioned on one side of the load-bearing axis and the second data storage device is positioned on an opposite side of the load-bearing axis.

17. The data storage apparatus of claim 16, wherein a horizontal displacement between the first data storage device and the load-bearing axis is substantially equal to a horizontal displacement between the second data storage device and the load-bearing axis.

18. The data storage apparatus of claim 14, wherein the first data storage device comprises a hard disk drive or a solid-state drive and the second data storage device comprises a hard disk drive or a solid-state drive.

19. The data storage apparatus of claim 14, wherein the first mounting plate and the second mounting plate form a vertically-oriented cavity in which a printed circuit board of the data storage device is to be installed.

20. The data storage apparatus of claim 19, wherein the vertically-oriented cavity is configured to guide air from the air supply opening to the air exhaust opening.
